(19) United States
(12) Patent Application Publication
(10) Pub. No.: US 2015/0054146 A1
(43) Pub. Date: Feb. 26, 2015

(54) SEMICONDUCTOR DEVICE

(71) Applicant: SUMITOMO BAKELITE CO., LTD., Tokyo (JP)

(72) Inventor: Shingo Itoh, Tokyo (JP)

(73) Assignee: SUMITOMO BAKELITE CO., LTD., Tokyo (JP)

(21) Appl. No.: 14/502,307

(22) Filed: Sep. 30, 2014

Related U.S. Application Data
(62) Division of application No. 13/519,226, filed on Jun. 26, 2012.

(30) Foreign Application Priority Data
Jan. 27, 2010 (JP) 2010-014919

(51) Int. Cl. H01L 21/56; H01L 23/00; H01L 23/31; H01L 23/495

(52) U.S. Cl. CPC H01L 21/56; H01L 23/49503; H01L 24/85; H01L 24/49; H01L 24/09; H01L 24/43; H01L 23/3114; H01L 2224/04042; H01L 2224/45139; H01L 2224/45144; H01L 2224/45147; H01L 2224/05164; H01L 2924/0132; H01L 2924/01202; H01L 2924/01105; H01L 2224/05144; H01L 2924/20103; H01L 2924/20104; H01L 2924/20105; H01L 2924/20106; H01L 2924/01201; H01L 2224/48247; H01L 2224/48091
USPC 257/676; 438/123

(57) ABSTRACT

A semiconductor device of the present invention includes a semiconductor element having an electrode pad; a substrate over which the semiconductor element is mounted and which has an electrical bonding part; and a bonding wire electrically connecting the electrode pad to the electrical bonding part, wherein a main metal component of the electrode pad is the same as or different from a main metal component of the bonding wire, and when the main metal component of the electrode pad is different from the main metal component of the bonding wire, a rate of interdiffusion of the main metal component of the bonding wire and the main metal component of the electrode pad at a junction of the bonding wire and the electrode pad under a post-curing temperature of an encapsulating resin is lower than that of interdiffusion of gold (Au) and aluminum (Al) at a junction of aluminum (Al) and gold (Au) under the post-curing temperature.

### CROSS-REFERENCE TO RELATED APPLICATIONS

The present application is a 37 C.F.R. §1.53(b) divisional of U.S. application Ser. No. 13/519,226 filed Jun. 26, 2012, which is the National Phase of PCT International Application No. PCT/JP2011/000286 filed Jan. 20, 2011, which claims priority on Japanese Patent Application No. 2010-014919 filed Jan. 27, 2010. The entire contents of each of these applications is hereby incorporated by reference.

### TECHNICAL FIELD

The present invention relates to a semiconductor device. Particularly, the present invention relates to a semiconductor device in which an electrode pad of a semiconductor element is electrically connected with a bonding wire and the semiconductor element and the bonding wire are encapsulated with a cured product of a thermosetting resin composition.

### BACKGROUND ART

Electronic parts such as diodes, transistors, and integrated circuits are conventionally encapsulated mainly with thermosetting resin compositions. Particularly, epoxy resin compositions containing an epoxy resin, a phenol resin-based curing agent, and an inorganic filler such as fused silica or crystalline silica and having excellent heat resistance and moisture resistance is used for integrated circuits. However, in accordance with recent market trends toward smaller-sized, lighter, and higher-performance electronic devices, the semiconductor elements have been enhancing higher integration year by year, and further surface mounting of semiconductor devices has been promoted. Under the circumstances, requirements for epoxy resin compositions used to encapsulate semiconductor elements have become increasingly strict.

On the other hand, environmental conditions under which semiconductor elements are used have become severe, and therefore bonding wires are also required to improve bonding reliability. Particularly, semiconductor elements for use in automobiles are required to improve the high-temperature reliability of junctions of electrode pads and bonding wires.

For example, Patent Document 1 describes that addition of Mn in an amount of 0.005 to 0.8 wt % to a gold alloy wire containing silver makes it possible to suppress a reduction in bonding strength after heating.

Patent Document 2 describes that addition of an appropriate alloying element to a bonding wire makes it possible to improve the long-term reliability of a junction of the bonding wire and an electrode and to achieve an increase in density, reductions in wire diameter and characteristic variations, and the like.

### RELATED DOCUMENTS

### Patent Documents

Patent Document 1: Japanese Patent Application Laid-Open Publication No. 9-272931

Patent Document 2: Japanese Patent Application Laid-Open Publication No. 2003-133362

### SUMMARY OF THE INVENTION

However, environmental conditions under which semiconductor elements are used have become more severe in recent years, and therefore semiconductor elements are required to be further improved to have high-temperature reliability.

For example, very high-temperature environments are present in automobiles, and therefore semiconductor elements for use in automobiles are required to have particularly excellent high-temperature storage characteristics and high-temperature operating characteristics. Poor connections between aluminum pads and gold wires in high-temperature storage or high-temperature operation are caused by void formation by Kirkendall effect. The improvement by reducing the growth rate of voids with using alloy wires (see, for example, Patent Documents 1 and 2) has not yet reached satisfactory levels.

In a semiconductor device in which an electrode pad of a semiconductor element is electrically connected with a bonding wire, and the semiconductor element and the bonding wire are encapsulated with a cured product of a thermosetting resin composition, the present invention relates to provide the semiconductor device which has excellent high-temperature storage characteristics and high-temperature operating characteristics.

The present invention is directed to a semiconductor device including:

a semiconductor element having an electrode pad;

a substrate over which the semiconductor element is mounted and which has an electrical bonding part;

a bonding wire electrically connecting the electrode pad to the electrical bonding part; and

a body of an encapsulating resin encapsulating the semiconductor element and the bonding wire and composed of a cured product of a thermosetting resin composition,

wherein a main metal component of the electrode pad is the same as or different from a main metal component of the bonding wire, and wherein when the main metal component of the electrode pad is different from the main metal component of the bonding wire, a rate of interdiffusion of the main metal component of the bonding wire and the main metal component of the electrode pad at a junction of the bonding wire and the electrode pad under a post-curing temperature of the encapsulating resin is lower than that of interdiffusion of gold (Au) and aluminum (Al) at a junction of aluminum (Al) and gold (Au) under the post-curing temperature.

According to the present invention, in a semiconductor device in which an electrode pad of a semiconductor element is electrically connected with a bonding wire, and the semiconductor element and the bonding wire are encapsulated with a cured product of a thermosetting resin composition, it is possible to obtain the semiconductor device having excellent high-temperature storage characteristics and high-temperature operating characteristics.

### BRIEF DESCRIPTION OF THE DRAWINGS

The above-described object, other objects, features, and advantages of the present invention will become more apparent by the following description of preferred embodiments given with reference to the accompanying drawings.

FIG. 1 is a diagram showing the cross-sectional structure of one example of a semiconductor device according to the present invention.

FIG. 2 is a diagram showing the cross-sectional structure of one example of a one side-encapsulated semiconductor device according to the present invention.

### DESCRIPTION OF EMBODIMENTS

Hereinbelow, a semiconductor device according to the present invention will be described in detail.

The semiconductor device according to the present invention includes: a semiconductor element having an electrode pad; a substrate over which the semiconductor element is mounted and which has an electrical bonding part; a bonding wire electrically connecting the electrode pad to the electrical bonding part; and a body of an encapsulating resin encapsulating the semiconductor element and the bonding wire and composed of a cured product of a thermosetting resin composition, wherein a main metal component of the electrode pad is the same as or different from a main metal component of the bonding wire, and wherein when the main metal component of the electrode pad is different from the main metal component of the bonding wire, a rate of interdiffusion of the main metal component of the bonding wire and the main metal component of the electrode pad at a junction of the bonding wire and the electrode pad under a post-curing temperature of the encapsulating resin is lower than that of interdiffusion of gold (Au) and aluminum (Al) at a junction of aluminum (Al) and gold (Au) under the post-curing temperature. Each of the components will be described in detail below.

The main metal component of the electrode pad of the semiconductor element used in the present invention is the same as the main metal component of the bonding wire, or is different from the main metal component of the bonding wire, and is a metal such that the growth rate of an alloy of the main metal component of the electrode pad of the semiconductor element and the main metal component of the bonding wire is lower than that of an alloy of gold and aluminum.

In the present invention, the main metal component of the electrode pad is contained in an amount of preferably 95 mass % or higher, more preferably 98 mass % or higher, even more preferably 99 mass % or higher with respect to the total mass of metal components contained in the electrode pad. In the present invention, the main metal component of the bonding wire is contained in an amount of preferably 90 mass % or higher, more preferably 95 mass % or higher, even more preferably 98 mass % or higher with respect to the total mass of metal components contained in the bonding wire.

The term “growth rate of an alloy” in the present invention refers to the rate of interdiffusion of metal components contained in two different metal materials at the time when the metal materials are brought into contact with each other under the post-curing temperature of the encapsulating resin. An alloy is formed at a junction of the dissimilar metal materials by interdiffusion of the metal components.

A comparison between the growth rate of an alloy of the main metal component of the electrode pad of the semiconductor element and the main metal component of the bonding wire and the growth rate of an alloy of gold and aluminum can be examined by comparing differences between the diffusion coefficients of metals under the post-curing temperature of the encapsulating resin. More specifically, the main metal component of the electrode pad and the main metal component of the bonding wire are brought into contact with each other under the post-curing temperature of the encapsulating resin to examine a difference (D1=|D_{p-w}−D_{w-p}|) between the diffusion coefficient of the main metal component of the electrode pad diffused in the main metal component of the bonding wire (D_{p-w}) and the diffusion coefficient of the main metal component of the bonding wire diffused in the main metal component of the electrode pad (D_{w-p}). Further, aluminum and gold are brought into contact with each other under the post-curing temperature of the encapsulating resin to examine a difference (D2=|D_{p-w}−D_{w-p}|) between the diffusion coefficient of aluminum diffused in gold (D_{Al—Au}) and the diffusion coefficient of gold diffused in aluminum (D_{Au—Al}). In the present invention, D1 and D2 satisfy the relation D1<D2. The post-curing temperature of the encapsulating resin may be set to, for example, 175° C.

Alternatively, the growth rate of an alloy may be measured in the following manner. A semiconductor device, in which an electrode pad of a semiconductor element is electrically connected with a bonding wire, and the semiconductor element and the bonding wire are encapsulated with a cured product of a thermosetting resin composition, is subjected to high-temperature treatment at a predetermined temperature for a predetermined time (for example, at 175° C. for 8 hours). Then, a wire-bonding portion on the electrode pad of the semiconductor element is cut, the cross-sectional surface of the wire-bonding portion is polished, and the growth thickness of an alloy region is measured with a laser microscope. The growth thickness is divided by the high-temperature treatment time to determine an alloy growth rate.

In the present invention, the substrate may be a lead frame having a die pad portion or a circuit board. In the lead frame, an external connection terminal such as an input-output terminal or a terminal for power source can be formed as the electrical bonding part. In the circuit board, an electrode pad can be provided as the electrical bonding part.

The bonding wire is used to electrically connect the electrode pad of the semiconductor element to an external connection terminal provided in a lead frame or a circuit board. The pad pitch and wire diameter of semiconductor elements are required to be smaller for higher integration, and specifically the wire diameter is required to be 30 μm or less, preferably 25 μm or less. The diameter of the bonding wire used in the semiconductor device according to the present invention is preferably 30 μm or less, more preferably 25 μm or less but 15 μm or more. The bonding wire used in the semiconductor device according to the present invention is not particularly limited, but preferably contains gold (Au), silver (Ag), or copper (Cu) as a main metal component. More specifically, the bonding wire is preferably composed of a gold alloy having a gold purity of 98 mass % or higher and containing at least one element selected from rare-earth elements, Ag, Be, Ca, Cu, Ga, Ge, In, Mg, Os, Pd, Rh, Ru, Sn, and Y in an amount of 0.0005 to 2.0 mass % from the viewpoint of ball's shape stability and bonding strength. The gold purity is more preferably 99 mass % (2N) or higher, particularly preferably 99.99 mass % (4N) or higher from the viewpoint of high-temperature storage characteristics and high-temperature operating characteristics. It is to be noted that the term “purity” used herein refers to the ratio of the amount of gold contained in the bonding wire to the total amount of metal components constituting the bonding wire.

In general, electrode pads of semiconductor elements use a metal mainly containing Al. However, Al contained in the electrode pads forms an alloy (intermetallic compound) with a gold alloy constituting bonding wires, and the growth of the alloy occurs during high-temperature storage or high-temperature operation at 100° C. or higher. At this time, voids are generated and grow by Kirkendall effect due to the difference between interdiffusion rates, which leads to an increase in resistance value and a disconnection. In the present invention, the main metal component of the electrode pad of the semiconductor element is the same as the main metal component of the bonding wire, or is a metal such that the growth rate of an alloy of the main metal component of the electrode pad of the semiconductor element and the main metal component of the bonding wire is lower than that of an alloy of aluminum and gold. This makes it possible to prevent the generation and growth of Kirkendall voids, thereby significantly improving the lifetime of the semiconductor device even when the semiconductor device is stored or operated under high temperature.

When the main metal component of the bonding wire is gold, the electrode pad of the semiconductor element preferably contains palladium (Pd) or gold (Au) as a main metal component, and more preferably consists of palladium (Pd) or gold (Au) from the viewpoint of moisture resistance reliability. The growth rate of an alloy of Pd and Au as the main metal component of the bonding wire is lower than that of an alloy of Au and Al, and therefore the semiconductor device has a long lifetime even when it is stored or operated under high temperature because the growth of Kirkendall voids is slow. On the other hand, Au is the same as the main metal component of the bonding wire, and therefore basically, the growth of an alloy does not occur and Kirkendall voids are not generated.

When the main metal component of the bonding wire is copper, the electrode pad of the semiconductor element preferably contains palladium (Pd) or gold (Au) as a main metal component, and more preferably consists of palladium (Pd) or gold (Au) from the viewpoint of moisture resistance reliability. The growth rate of an alloy of Pd or Au and Cu as the main metal component of the bonding wire is lower than that of an alloy of Au and Al, and therefore the semiconductor device has a long lifetime even when it is stored or operated under high temperature because the growth of Kirkendall voids is slow.

When the main metal component of the bonding wire is silver, the electrode pad of the semiconductor element preferably contains palladium (Pd) or gold (Au) as a main metal component, and more preferably consists of palladium (Pd) or gold (Au) from the viewpoint of moisture resistance reliability. The growth rate of an alloy of Pd or Au and Ag as the main metal component of the bonding wire is lower than that of an alloy of Au and Al, and therefore the semiconductor device has a long lifetime even when it is stored or operated under high temperature because the growth of Kirkendall voids is slow.

The electrode pad may contain at least one selected from Al, Cu, Cr, Ti, and Si as a metal other than the main metal component, and the amount of such a metal contained in the electrode pad is preferably 0 to 2 mass %.

Hereinbelow, a thermosetting resin composition used to produce the semiconductor device according to the present invention will be described. The thermosetting resin composition is molded and cured to form an encapsulating body. The thermosetting resin composition used to produce the semiconductor device according to the present invention is not particularly limited and may contain one or more thermosetting resins such as urea resins, melamine resins, phenol resins, resorcinol resins, epoxy resins, polyurethane resins, vinyl acetate resins, polyvinyl alcohol resins, acrylic resins, vinyl urethane resins, silicone resins, α-olefin maleic anhydride resins, polyamide resins, and polyimide resins along with a curing agent, and a curing catalyst. The epoxy resin composition containing an epoxy resin (A), a curing agent (B), and an inorganic filler (C) is preferably used as the thermosetting resin composition. Each of the components of the epoxy resin composition used to produce the semiconductor device according to the present invention will be described below.

The epoxy resin composition used to produce the semiconductor device according to the present invention may use an epoxy resin (A). The epoxy resins (A) usable in the present invention include all monomers, oligomers, and polymers containing two or more epoxy groups in one molecule, and molecular weight and molecular structure thereof are not particularly limited. Examples of such epoxy resins (A) include: crystalline epoxy resins such as biphenyl-type epoxy resins, bisphenol-type epoxy resins, and stilbene-type epoxy resins; novolac-type epoxy resins such as phenol novolac-type epoxy resins and cresol novolac-type epoxy resins; polyfunctional epoxy resins such as triphenolmethane-type epoxy resins and alkyl-modified triphenolmethane-type epoxy resins; aralkyl-type epoxy resins such as phenylene structure-containing phenolaralkyl-type epoxy resins and biphenylene structure-containing phenolaralkyl-type epoxy resins; naphthol-type epoxy resins such as dihydroxynaphthalene-type epoxy resins and epoxy resins obtained by glycidyl etherification of dimers of dihydroxynaphthalene; triazine nucleus-containing epoxy resins such as triglycidyl isocyanurate and monoallyldiglycidyl isocyanurate; and bridged cyclic hydrocarbon compound-modified phenol-type epoxy resins such as dicyclopentadiene-modified phenol-type epoxy resins. These epoxy resins may be used singly or in combination of two or more of them. Polyfunctional epoxy resins such as triphenolmethane-type epoxy resins and alkyl-modified triphenolmethane-type epoxy resins are preferred from the viewpoint of further improving high-temperature storage characteristics and high-temperature operating characteristics, and triphenolmethane-type epoxy resins are particularly preferred.

The lower limit of the total epoxy resin (A) content is not particularly limited, but is preferably 3 mass % or more, more preferably 5 mass % or more with respect to the total mass of the epoxy resin composition. When the total epoxy resin (A) content is within the above range, there is little fear that wire breakage will be caused by an increase in viscosity. The upper limit of the total epoxy resin (A) content is not particularly limited, but is preferably 15 mass % or less, more preferably 13 mass % or less with respect to the total mass of the epoxy resin composition. When the upper limit of the total epoxy resin content is within the above range, there is little fear that moisture resistance reliability will be reduced by an increase in water absorption rate.

The epoxy resin composition used to produce the semiconductor device according to the present invention may use a curing agent (B). The curing agents (B) usable in the present invention are roughly divided into three types such as polyaddition type, catalyst type, and condensation type.

Examples of the polyaddition-type curing agent include: polyamine compounds including aliphatic polyamines such as diethylenetriamine (DETA), triethylenetetramine (TETA), and metaxylylenediamine (MXDA); aromatic polyamines such as diaminodiphenylmethane (DDM), m-phenylenediamine (MPDA), and diaminodiphenylsulfone (DDS), dicyandiamide (DICY), and organic acid dihydrazides; acid anhydrides including alicyclic acid anhydrides such as hexahydrophthalic anhydride (HHPA) and methyltetrahydrophthalic anhydride (MTHPA) and aromatic acid anhydrides such as trimellitic anhydride (TMA), pyromellitic anhydride (PMDA), and benzophenonetetracarboxylic acid (BTDA); polyphenol compounds such as novolac-type phenol resins and phenol polymers; polymercaptan compounds such as polysulfides, thioesters, and thioethers; isocyanate compounds such as isocyanate prepolymers, blocked isocyanates; and organic acids such as carboxylic acid-containing polyester resins.

Examples of the catalyst-type curing agent include: tertiary amine compounds such as benzyldimethylamine (BDMA) and 2,4,6-trisdimethylaminomethylphenol (DMP-30); imidazole compounds such as 2-methylimidazole and 2-ethyl-4-methylimidazole (EMI24); Lewis acids such as BF3 complexes.

Examples of the condensation-type curing agent include: phenol resin-based curing agents such as novolac-type phenol resins and resol-type phenol resins; urea resins such as methylol group-containing urea resins; and melamine resins such as methylol group-containing melamine resins.

Among them, phenol resin-based curing agents are preferred from the viewpoint of a balance among flame resistance, moisture resistance, electric characteristics, curability, and storage stability. The phenol resin-based curing agents include all monomers, oligomers, and polymers having two or more phenolic hydroxyl groups in one molecule, and molecular weight and molecular structure thereof are not particularly limited. Examples of such phenol resin-based curing agents include: novolac-type resins such as phenol novolac resins and cresol novolac resins; polyfunctional-type phenol resins such as triphenolmethane-type phenol resins; modified phenol resins such as terpene-modified phenol resins and dicyclopentadiene-modified phenol resins; aralkyl-type resins such as phenylene structure—and/or biphenylene structure-containing phenol aralkyl resins and phenylene- and/or biphenylene structure-containing naphthol aralkyl resins; and bisphenol compounds such as bisphenol A and bisphenol F. These resins may be used singly or in combination of two or more of them. Polyfunctional-type phenol resins such as triphenolmethane-type phenol resins are preferred from the viewpoint of further improving high-temperature storage characteristics and high-temperature operating characteristics, and triphenolmethane-type phenol resins are particularly preferred.

The lower limit of the total curing agent (B) content is not particularly limited, but is preferably 0.8 mass % or more, more preferably 1.5 mass % or more with respect to the total mass of the epoxy resin composition. When the lower limit of the total curing agent (B) content is within the above range, sufficient fluidity is achieved. The upper limit of the total curing agent (B) content is not particularly limited either, but is preferably 10 mass % or less, more preferably 8 mass % or less with respect to the total mass of the epoxy resin composition. When the upper limit of the total curing agent (B) content is within the above range, there is little fear that moisture resistance reliability will be reduced by an increase in water absorption rate.

When a phenol resin-based curing agent is used as the curing agent (B), the epoxy resin and the phenol resin-based curing agent are preferably mixed so that the equivalent ratio of the total number of epoxy groups (EP) in the epoxy resin to the total number of phenolic hydroxyl groups (OH) in the phenol resin-based curing agent ((EP)/(OH)) is 0.8 or more and 1.3 or less. The equivalent ratio within the above range causes less the reduction of the curability of the semiconductor encapsulating epoxy resin composition or the decline of the physical properties of the resin cured product.

The epoxy resin composition used to produce the semiconductor device according to the present invention may use an inorganic filler (C). The inorganic filler (C) used may be one generally used in semiconductor encapsulating epoxy resin compositions. Examples of such inorganic filler (C) include fused silica, crystalline silica, talc, alumina, titanium white, and silicon nitride. Among them, fused silica is most preferably used. These inorganic fillers (C) may be used singly or in combination of two or more of them. Further, these inorganic fillers (C) may be surface-treated with a coupling agent. The filler preferably has a shape as close to a perfect sphere as possible and a broad particle size distribution in order to improve fluidity. The inorganic filler (C) preferably contains particles whose size is two-thirds or less of a wire pitch width in an amount of 99.9 mass % or more from the viewpoint of application to semiconductor devices with a narrow wire pitch. The inorganic filler (C) having such particles in an amount within the above range can suppress the occurrence of the insufficient filled epoxy resin composition or the wire sweep caused by coarse particles sticking between the wires. Such the inorganic filler (C) can be obtained by directly using commercially-available inorganic filler, or by preparing such as mixing two or more commercially-available inorganic fillers, or by passing the mixture through a screen. The particle size distribution of the inorganic filler can be measured by a commercially-available laser particle size analyzer (for example, SALD-7000 manufactured by Shimadzu Corporation), or the like.

The inorganic filler (C) content is not particularly limited, but the lower limit of the inorganic filler (C) content is preferably 82 mass % or more, more preferably 85 mass % or more with respect to the total mass of the epoxy resin composition. When the inorganic filler (C) content is not less than the above lower limit, low moisture absorptivity and low thermal expansibility are achieved and therefore there is little fear that moisture resistance reliability will be poor. The upper limit of the inorganic filler (C) content is preferably 92 mass % or less, more preferably 89 mass % or less with respect to the total mass of the epoxy resin composition. When the inorganic filler (C) content does not exceed the above upper limit, there is little fear that defective filling and the like will be caused during molding due to a reduction in fluidity or the semiconductor device will have a problem such as wire sweep caused by an increase in viscosity.

The epoxy resin composition used to produce the semiconductor device according to the present invention may further use a curing accelerator (D). The curing accelerator (D) is not particularly limited as long as it can accelerate a cross-linking reaction between epoxy groups of the epoxy resin and functional groups of the curing agent (for example, phenolic hydroxyl groups of a phenol resin-based curing agent). The curing accelerator (D) used in the present invention may be one usually used in epoxy resin compositions. Examples of such a curing accelerator (D) include diazabicycloalkenes and derivatives thereof such as 1,8-diazabicyclo(5,4,0)undecene-7; organic phosphines such as triphenylphosphine and methyldiphenylphosphine; imidazole compounds such as 2-methylimidazole; tetra-substituted phosphonium•tetra-substituted borate such as tetraphenylphosphonium•tetraphenyl borate; and adducts of phosphine compounds with quinone compounds. These curing accelerators may be used singly or in combination of two or more of them.

The lower limit of the curing accelerator (D) content is not particularly limited, but is preferably 0.05 mass % or more, more preferably 0.1 mass % or more with respect to the total mass of the epoxy resin composition. When the lower limit of the curing accelerator (D) content is within the above range, there is little fear that curability will be reduced. The upper limit of the curing accelerator (D) content is not particularly limited, but is preferably 1 mass % or less, more preferably 0.5 mass % or less with respect to the total mass of the epoxy resin composition. When the upper limit of the curing accelerator (D) content is within the above range, there is little fear that fluidity will be reduced.

When necessary, the epoxy resin composition used to produce the semiconductor device according to the present invention may further contain any additive. Examples of such an additive include: aluminum corrosion inhibitors such as zirconium hydroxide; inorganic ion exchangers such as bismuth oxide hydrate; coupling agents such as γ-glycidoxypropyltrimethoxysilane, 3-mercaptopropyltrimethoxysilane, and 3-aminopropyltrimethoxysilane; coloring agents such as carbon black and iron red; low-stress components such as silicone rubbers; releasing agents such as natural waxes (for example, carnauba wax), synthetic waxes, higher fatty acids and metal salts thereof (for example, zinc stearate), and paraffin; and antioxidants. When necessary, the inorganic filler may be also treated with an epoxy resin or a phenol resin in advance. Examples of the treating method include one in which a solvent is removed after mixing the inorganic filler and an epoxy resin or a phenol resin using the solvent, and one in which an epoxy resin or a phenol resin is directly added to the inorganic filler and then mixed by using a mixer.

The epoxy resin composition used to produce the semiconductor device according to the present invention may be prepared by mixing the above-described components with the use of a mixer or the like at room temperature, or then adjusted dispersion degree, fluidity or the like as necessary by melting and kneading with using a kneading machine such as rolls, a kneader, or an extruder, and then cooled before crushed.

Hereinbelow, the semiconductor device according to the present invention will be described. The thermosetting resin composition is cured and molded by a conventional molding method such as transfer molding, compression molding, or injection molding so that the cured product encapsulates an electronic part such as a semiconductor element and a bonding wire or the like, to obtain the semiconductor device according to the present invention. When a semiconductor encapsulating epoxy resin composition is molded and cured by transfer molding or compression molding, the epoxy resin composition in the form of powder or granules may be directly used, or may be compressed into tablets before use. The semiconductor device encapsulated by a molding method such as transfer molding is mounted on an electronic device or the like directly or after complete curing at a temperature of about 80° C. to 200° C. for about 10 minutes to 10 hours.

The semiconductor element used in the present invention is not particularly limited, and examples thereof include integrated circuits, large-scale integrated circuits, transistors, thyristors, diodes, and solid-state image sensing devices.

The form of the semiconductor device according to the present invention is not particularly limited, and examples thereof include Dual-Inline Package (DIP), Plastic-Leaded Chip Carrier (PLCC), Quad Flat Package (QFP), Small Outline Package (SOP), Small Outline J-Lead Package (SOJ), Thin Small-Outline Package (TSOP), Thin Quad Flat Package (TQFP), Tape Carrier Package (TCP), Ball Grid Array (BGA), and Chip Size Package (CSP).

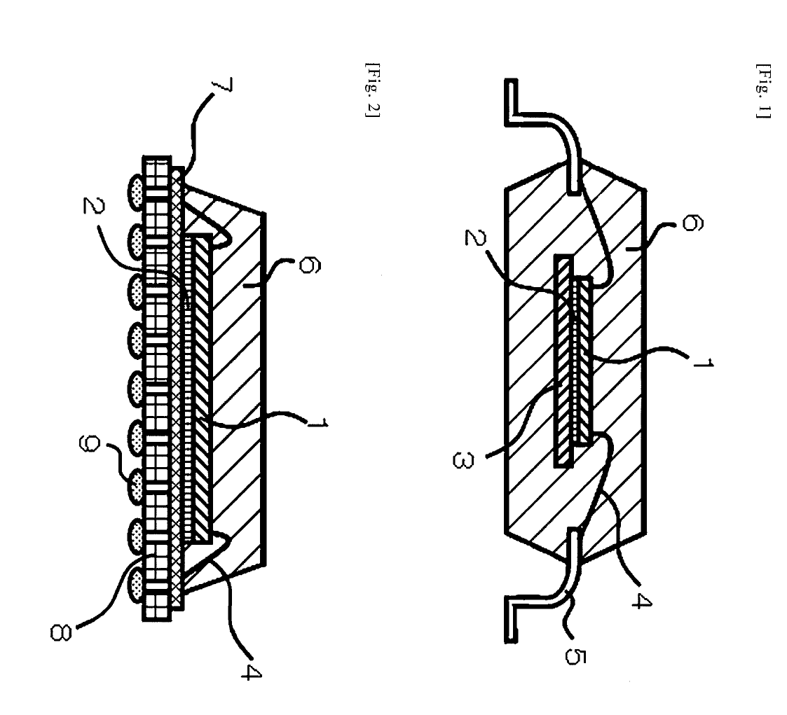

FIG. 1 is a diagram showing the cross-sectional structure of one example of a semiconductor device according to the present invention. A semiconductor element 1 is fixed onto a die pad 3 by a cured die bonding material 2 interposed between them. Terminals (not shown) of a lead frame 5 and electrode pads of the semiconductor element 1 are connected to each other by bonding wires 4. The semiconductor element 1 is encapsulated with a cured product 6 of a thermosetting resin composition.

FIG. 2 is a diagram showing the cross-sectional structure of one example of a one side-encapsulated semiconductor device according to the present invention. The semiconductor element 1 is fixed onto a layer of a solder resist 7 stacked on the surface of a circuit board 8 by the cured die bonding material 2 interposed between the semiconductor element 1 and the solder resist 7. The solder resist 7 on electrode pads of the circuit board 8 is removed by a development method so that the electrode pads are exposed in order to establish continuity between the semiconductor element 1 and the circuit board 8. The electrode pads of the semiconductor element 1 are connected to the electrode pads of the circuit board 8 through the bonding wires 4. Only the one side of the circuit board 8 having the semiconductor element 1 is encapsulated with the cured product 6 of an encapsulating resin composition. The electrode pads on the circuit board 8 are internally connected to solder balls 9 provided on the non-encapsulated side of the circuit board 8.

Such semiconductor devices according to the present invention have excellent high-temperature storage characteristics and high-temperature operating characteristics, and can operates successfully at 175° C. for 1000 hours or longer without any failure during operation even after storage at 200° C. for 2000 hours. Therefore, the semiconductor device according to the present invention can be used even in a high-temperature environment of 120° C. or higher, and is especially suitable for use in automobiles.

Although the present invention has been described above with reference to the embodiments, these embodiments are merely examples of the present invention, and various structures other than the above-described structures may be employed.

For example, in the examples shown in FIGS. 1 and 2, one semiconductor element is mounted over a die pad portion of a lead frame or on a circuit board, but two or more semiconductor elements may be mounted over a die pad portion or on a circuit board.

Further, another embodiment of the semiconductor device according to the present invention is, for example, a semiconductor device including: a lead frame having a die pad portion or a circuit board; one or more semiconductor elements mounted over the die pad portion of the lead frame or on the circuit board; a bonding wire electrically connecting an electrical bonding part provided in the lead frame or in the circuit board to an electrode pad provided in the semiconductor element; and an encapsulating body encapsulating the semiconductor element and the bonding wire, wherein a main metal component of the electrode pad of the semiconductor element is the same as a main metal component of the bonding wire, or is different from the main metal component of the bonding wire and is a metal such that a growth rate of an alloy of the main metal component of the electrode pad of the semiconductor element, and the main metal component of the bonding wire is lower than that of an alloy of gold and aluminum, and wherein the encapsulating body is composed of a cured product of an epoxy resin composition containing an epoxy resin (A), a curing agent (B), and an inorganic filler (C).

### EXAMPLES

Hereinbelow, examples of the present invention will be described, but the present invention is not limited to these examples. The amounts of components mixed are expressed in parts by mass. The components of epoxy resin compositions prepared in examples and comparative examples will be listed below.

(Epoxy Resins)

Orthocresol novolac-type epoxy resin (E-1: manufactured by Nippon Kayaku Co., Ltd., EOCN1020, softening point: 55° C., epoxy equivalent: 196 g/eq)

Biphenylene structure-containing phenolaralkyl-type epoxy resin (E-2: manufactured by Nippon Kayaku Co., Ltd., NC3000, softening point: 58° C., epoxy equivalent: 274 g/eq)

Triphenolmethane-type epoxy resin (E-3: manufactured by Japan Epoxy Resin Co., Ltd., E-1032H60, softening point: 59° C., epoxy equivalent: 171 g/eq)

(Curing Agents)

Phenol novolac resin (H-1: manufactured by Sumitomo Bakelite Co., Ltd., PR-HF-3, softening point: 80° C., hydroxyl equivalent 104 g/eq)

Biphenylene structure-containing phenolaralkyl resin (H-2: manufactured by Meiwa Plastic Industries Ltd., MEH-7851SS, softening point: 65° C., hydroxyl equivalent 203 g/eq)

Triphenolmethane-type phenol resin (H-3: manufactured by Meiwa Plastic Industries Ltd., MEH-7500, softening point: 110° C., hydroxyl equivalent: 97 g/eq)

(Inorganic Filler)

Fused spherical silica (manufactured by Micron Co., Ltd., HS-104, average particle size: 26.5 μm, percentage of particles with a diameter of 105 μm or more: 1% or less)

(Other Additives)

Curing accelerator: Triphenylphosphine (TPP), Silane coupling agent (epoxysilane: γ-glycidoxypropyltrimethoxysilane)

Coloring agent: Carbon black

Releasing agent: Carnauba wax

### Preparation of Epoxy Resin Composition

### Example 1

| | |
|---|---|
| E-1 | 9.2 parts by mass |
| H-1 | 4.8 parts by mass |
| Fused spherical silica | 85.0 parts by mass |
| Triphenylphosphine | 0.1 part by mass |
| Epoxysilane | 0.2 part by mass |
| Carbon black | 0.3 part by mass |
| Carnauba wax | 0.4 part by mass |

The above components were mixed using a mixer at room temperature, and then roll-kneaded at 70 to 100° C., cooled, and crushed to obtain an epoxy resin composition.

### Examples 2 to 7 and Comparative Examples 1 and 2

An epoxy resin composition was obtained according to formulation shown in Table 1 in the same manner as in Example 1.

Production of Semiconductor Device

Silicon chips and the like were encapsulated with an epoxy resin composition and molded using a low-pressure transfer molding machine (manufactured by KOHTAKI Corporation, KTS-125) under conditions of a molding temperature of 175° C., an injection pressure of 6.9 MPa, and a curing time of 120 seconds to obtain a 16-pin SOP (package size: 7.2 mm×11.5 mm, thickness: 1.95 mm, one evaluation circuit connecting in series three units, and each of the units having the two passivation openings of a test element group (TEG) listed below, which is bonded with Au wires (NL-4 manufactured by Sumitomo Metal Mining Co., Ltd, Au 99.99 mass %, 25 μmØ), so as to connect to the inner leads of a lead frame by wire-bonded). Then the 16-pin SOP was heated at 175° C. for 8 hours for post curing.

TEG1: size 3.5 mm×3.5 mm, thickness 0.35 mm, electrode pad: Pd-0.6 μm thick, 115 μm×125 μm, passivation opening: 95 μm×100 μm×2

TEG2: size 3.5 mm×3.5 mm, thickness 0.35 mm, electrode pad: Au-0.6 μm thick, 115 μm×125 μm, passivation opening: 95 μm×100 μm×2

TEG3: size 3.5 mm×3.5 mm, thickness 0.35 mm, electrode pad: Al (99.5 mass %)-Cu (0.5 mass %) alloy-0.6 μm thick, 115 μm×125 μm, passivation opening: 95 μm×100 μm×2

The epoxy resin compositions and the semiconductor devices obtained in Examples and Comparative Examples were evaluated by the following methods. The evaluation results are shown in Table 1.

Evaluation Methods

Spiral Flow: The epoxy resin composition was injected into a spiral flow test mold specified in ANSI/ASTM D 3123-72 with the use of a low-pressure transfer molding machine (KTS-15 manufactured by KOHTAKI Corporation) under the conditions of a mold temperature of 175° C., an injection pressure of 6.9 MPa, and a curing time of 120 seconds, and a flow length was measured. The flow length was expressed in centimeters.

Alloy Growth Rate: The wire-bonding portion of the 16-pin SOP subjected to post curing (175° C., 8 hours) was cut, and its cross-sectional surface was polished by a cross-section polisher (SM-09020CP manufactured by JEOL Ltd.) to measure the thickness of an alloy region with a laser microscope (VK-9700 manufactured by KEYENCE Corporation).

High-Temperature Storage Characteristics: Fifteen 16-pin SOP packages (fifteen evaluation circuits) subjected to post curing (175° C., 8 hours) were prepared, and the electric resistance of each of the evaluation circuits was measured with a digital multimeter (ADVANTEST R6441A manufactured by ADVANTEST Corporation) and recorded. Then, the 16-pin SOP packages were subjected to a high-temperature storage test (200° C., 2000 hours, no voltage applied), and then the electric resistance of each of the evaluation circuits was again measured with the digital multimeter. When the electric resistance of evaluation circuit of a 16-SOP package was increased by 20% from the initial value, the 16-pin SOP package was evaluated as defective. When the number of defective packages is n, the evaluation result is expressed as “n/15”.

High-Temperature Operating Characteristics: Fifteen 16-pin SOP packages (fifteen evaluation circuits) subjected to post curing (175° C., 8 hours) were prepared, and the electric resistance of each of the evaluation circuits was measured with a digital multimeter (ADVANTEST R6441A manufactured by ADVANTEST Corporation) and recorded. Then, the 16-pin SOP packages were subjected to a high-temperature operation test (0.1 A of direct current was applied to the evaluation circuit at 175° C. for 1000 hours), and then the electric resistance of each of the evaluation circuits was again measured with the digital multimeter. When the electric resistance of evaluation circuit of a 16-SOP package was increased by 20% from the initial value, the 16-pin SOP package was evaluated as defective. When the number of defective packages is n, the evaluation result is expressed as “n/15”.

TABLE 1

| | | Examples | | | | | | | Comparative Examples | |
|---|---|---|---|---|---|---|---|---|---|---|
| | | 1 | 2 | 3 | 4 | 5 | 6 | 7 | 1 | 2 |
| Formulation | E-1 | 9.2 | 9.2 | | | | 9.4 | | 9.2 | |
| of Resin | E-2 | | | 7.5 | 7.5 | | | | | 7.5 |
| Composition | E-3 | | | | | 8.7 | | 9.0 | | |
| (parts by | H-1 | 4.8 | 4.8 | | | 5.3 | | | 4.8 | |
| mass) | H-2 | | | 5.5 | 5.5 | | | | | 5.5 |
| | H-3 | | | | | | 4.6 | 5.0 | | |
| | Fused Spherical Silica | 85 | 85 | 86 | 86 | 85 | 85 | 85 | 85 | 86 |
| | TPP | 0.1 | 0.1 | 0.1 | 0.1 | 0.1 | 0.1 | 0.1 | 0.1 | 0.1 |
| | Epoxysilane | 0.2 | 0.2 | 0.2 | 0.2 | 0.2 | 0.2 | 0.2 | 0.2 | 0.2 |
| | Carbon Black | 0.3 | 0.3 | 0.3 | 0.3 | 0.3 | 0.3 | 0.3 | 0.3 | 0.3 |
| | Carnauba Wax | 0.4 | 0.4 | 0.4 | 0.4 | 0.4 | 0.4 | 0.4 | 0.4 | 0.4 |
| Equivalent Ratio (EP/OH) | | 1.02 | 1.02 | 1.01 | 1.01 | 1.00 | 1.01 | 1.02 | 1.02 | 1.01 |
| Bonding Wire | Main Metal Component | Au | Au | Au | Au | Au | Au | Au | Au | Au |
| T | TEG Name | TEG1 | TEG2 | TEG1 | TEG2 | TEG1 | TEG1 | TEG1 | TEG3 | TEG3 |
| E | Main Metal Component of Electrode Pad | Pd | Au | Pd | Au | Pd | Pd | Pd | Al | Al |
| G | Thickness of Electrode Pad (μm) | 0.6 | 0.6 | 0.6 | 0.6 | 0.6 | 0.6 | 0.6 | 0.6 | 0.6 |
| Evaluation | Spiral Flow (cm) | 83 | 63 | 71 | 71 | 90 | 96 | 72 | 83 | 71 |
| Results | Alloy Growth Rate (μm/8 hr) | 0.7 | No alloy | 0.8 | No alloy | 0.6 | 0.6 | 0.5 | 3.8 | 4.1 |
| | High-Temperature Storage Characteristics | 0/15 | 0/15 | 0/15 | 0/15 | 0/15 | 0/15 | 0/15 | 15/15 | 15/15 |
| | High-Temperature Operating Characteristics | 0/15 | 0/15 | 0/15 | 0/15 | 0/15 | 0/15 | 0/15 | 15/15 | 15/15 |

As can be seen from Table 1, the semiconductor devices of Examples 1 to 7 had excellent high-temperature storage characteristics and high-temperature operating characteristics.

1. A method of manufacturing a semiconductor device comprising:
molding a semiconductor element and a bonding wire with a thermosetting resin composition; and
curing said thermosetting resin composition at a post-curing temperature of said thermosetting resin composition;
wherein the produced semiconductor device comprises:
said semiconductor element having an electrode pad;
a substrate over which the semiconductor element is mounted and which has an electrical bonding part;
said bonding wire electrically connecting the electrode pad to the electrical bonding part; and
a body of an encapsulating resin encapsulating said semiconductor element and said bonding wire and composed of a cured product of said thermosetting resin composition,
wherein a main metal component of said electrode pad is different from a main metal component of said bonding wire, and
wherein a rate of interdiffusion of the main metal component of said bonding wire and the main metal component of said electrode pad at a junction of said bonding wire and said electrode pad molded with said thermosetting resin composition is 0.8 μm/8 hr or less in said curing step.

2. The method of manufacturing a semiconductor device according to claim 1,
wherein the main metal component of said electrode pad is gold (Au) or palladium (Pd), and
wherein the main metal component of said bonding wire is gold (Au), copper (Cu), or silver (Ag).

3. An automobile comprising a semiconductor device made by the method of manufacturing a semiconductor device according to claim 1.

4. The method of manufacturing a semiconductor device according to claim 1, wherein said bonding wire contains gold (Au) in an amount of 99 mass % or more with respect to a total mass of metal components constituting said bonding wire.

5. The method of manufacturing a semiconductor device according to claim 4, wherein said electrode pad consists of palladium (Pd).

6. The method of manufacturing a semiconductor device according to claim 1, wherein said bonding wire consists of a gold alloy having a gold purity of 98 mass % or higher and containing at least one element selected from rare-earth elements, Ag, Be, Ca, Cu, Ga, Ge, In, Mg, Os, Pd, Rh, Ru, Sn, and Y in an amount of 0.0005 to 2.0 mass %.

7. The method of manufacturing a semiconductor device according to claim 1,
wherein said substrate is a lead frame having a die pad portion, and
wherein said semiconductor element is mounted over the die pad portion.

8. The method of manufacturing a semiconductor device according to claim 1, wherein said thermosetting resin composition contains an epoxy resin composition containing an epoxy resin (A), a curing agent (B), and an inorganic filler (C).

9. The method of manufacturing a semiconductor device according to claim 8, wherein the epoxy resin (A) is a polyfunctional epoxy resin.

10. The method of manufacturing a semiconductor device according to claim 1, wherein said post-curing temperature is 80° C. to 200° C.
